(19) United States
(12) Patent Application Publication
(10) Pub. No.: US 2023/0307415 A1
(43) Pub. Date: Sep. 28, 2023

(54) SEMICONDUCTOR DEVICE AND SEMICONDUCTOR DEVICE MANUFACTURING METHOD

(71) Applicant: KIOXIA CORPORATION, Tokyo (JP)

(72) Inventors: Satoshi HONGO, Yokkaichi Mie (JP); Tatsuo MIGITA, Nagoya Aichi (JP); Gen TOYOTA, Yokkaichi Mie (JP)

(21) Appl. No.: 17/899,260

(22) Filed: Aug. 30, 2022

(30) Foreign Application Priority Data
Mar. 22, 2022 (JP) 2022-045424

(51) Int. Cl. H01L 25/065; H01L 23/31; H01L 23/29; H01L 23/48; H01L 25/00; H01L 21/56

(52) U.S. Cl. CPC H01L 25/0652; H01L 23/3128; H01L 23/291; H01L 23/481; H01L 23/3135; H01L 25/50; H01L 21/56

(57) ABSTRACT

According to one embodiment, a semiconductor device includes a base substrate with an interconnection layer and a plurality of chips stacked on the base substrate. A protective film is between each adjacent pair of chips in the plurality of chips stacked on the base substrate and on side surfaces of at least each chip in the plurality other than an uppermost chip in the stacked plurality of chips. A lowermost chip in the stacked plurality of chips has a metal pad electrically connected to the interconnection layer. Each chip in an adjacent pair of chips in the plurality of chips stacked on the base substrate has an electrode contacting an electrode of the other chip in the adjacent pair.

### CROSS-REFERENCE TO RELATED APPLICATION(S)

This application is based upon and claims the benefit of priority from Japanese Patent Application No. 2022-045424, filed Mar. 22, 2022, the entire contents of which are incorporated herein by reference.

### FIELD

Embodiments described herein relate generally to a semiconductor device and a semiconductor device manufacturing method.

### BACKGROUND

As an example of a semiconductor device and a semiconductor device manufacturing method, a stacked device chip and a stacked device chip manufacturing method are known.

### BRIEF DESCRIPTION OF THE DRAWINGS

FIG. 1 illustrates a semiconductor storage device according to a first embodiment.

FIGS. 2 to 7 illustrates aspects related to a method of manufacturing a semiconductor storage device according to a first embodiment.

FIG. 8 is an enlarged view of part XI of FIG. 7.

FIG. 9 illustrates additional aspects related to a method of manufacturing a semiconductor storage device according to a first embodiment.

FIG. 10 illustrates a chip provided in the semiconductor storage device according to a first embodiment.

FIG. 11 illustrates a joining of a chip and a base substrate.

FIG. 12 illustrates a modification of a base substrate.

FIG. 13 illustrates a chip-to-chip joining.

FIGS. 14 to 16 illustrates aspects related to a chip-to-chip joining.

FIG. 17 illustrates a semiconductor storage device according to a modification.

FIG. 18 illustrates configurations of a semiconductor storage device according to a second embodiment.

FIGS. 19 to 28 illustrates aspects related to a method of manufacturing a semiconductor storage device according to a second embodiment.

### DETAILED DESCRIPTION

Embodiments enables a smaller pitch in a semiconductor device.

In general, according to one embodiment, a semiconductor device includes a base substrate with an interconnection layer and a plurality of chips stacked on the base substrate. A protective film is between each adjacent pair of chips in the plurality of chips stacked on the base substrate and on side surfaces of at least each chip in the plurality other than an uppermost chip in the stacked plurality of chips. A lowermost chip in the stacked plurality of chips has a metal pad electrically connected to the interconnection layer. Each chip in an adjacent pair of chips in the plurality of chips stacked on the base substrate has an electrode contacting an electrode of the other chip in the adjacent pair.

Hereinafter, certain example embodiments of the present disclosure will be described with reference to the drawings. For facilitating understanding descriptions, the same elements depicted in different drawings are denoted by same reference symbols and repetitive descriptions thereof may be omitted.

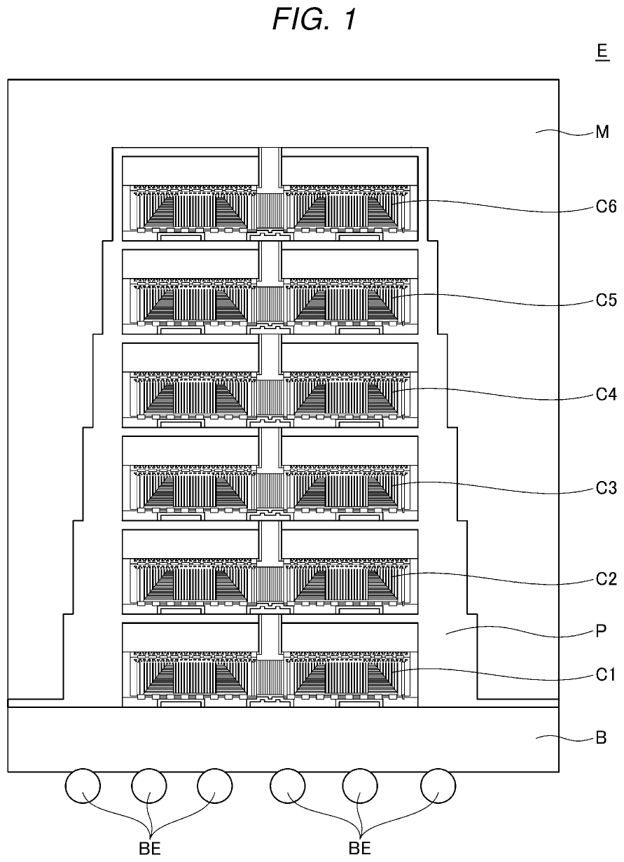

FIG. 1 illustrates a structure of a semiconductor storage device E according to a first embodiment. The semiconductor storage device E includes a base substrate B and chips C1, C2, C3, C4, C5, and C6. The chip C1 is joined onto the base substrate B. On the base substrate B, a plurality of metal balls BE (solder balls) are joined to an opposite surface of the base substrate B from the surface of the base substrate B to which the chip C1 is joined.

A chip C2 is joined to a surface of the chip C1. A chip C3 is joined to a surface of the chip C2. A chip C4 is joined to a surface of the chip C3. A chip C5 is joined to a surface of the chip C4. A chip C6 is joined to a surface of the chip C5. In this way, the chips C1, C2, C3, C4, C5, and C6 are stacked on the base substrate B one upon the other.

A protective film P covers side surfaces of the chips C1, C2, C3, C4, C5, and C6. The protective film P also covers at least part of the base substrate B. In the present embodiment, the protective film P is provided, for example, such that the protective film P is relatively thick on side portion adjacent to the chip C1 and relatively thin on side portion adjacent to the chip C6. A thickness of the protective film P is not limited to this example and the protective film P may be provided at a uniform thickness in other examples. In still other examples, the protective film P may be provided such that the protective film P is relatively thick on the side portion adjacent to the chip C6 and relatively thin on the side portion adjacent to the chip C1. The protective film P may be omitted in some examples. A mold resin layer M covers the protective film P and the chips C1, C2, C3, C4, C5, and C6.

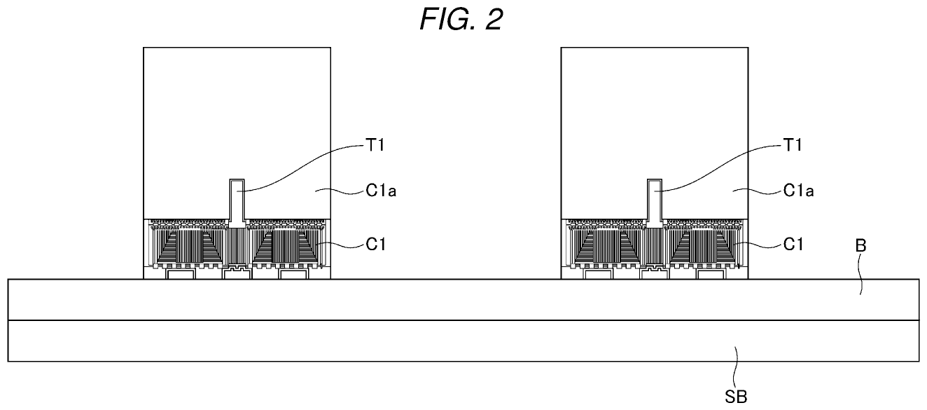

Next, a method of manufacturing the semiconductor storage device E will be described with reference to FIGS. 2 to 9. While FIGS. 2 to 9 illustrate manufacturing of two semiconductor storage devices E, many (e.g., three or more) semiconductor storage devices E may be manufactured at the same time.

As illustrated in FIG. 2, a base substrate B applied onto a supporting substrate SB is prepared. The base substrate B may be prepared by forming an interconnection layer on the supporting substrate SB. A predetermined number of chips C1 that have been separated from each other by dicing are bonded onto predetermined positions on the base substrate B. In each chip C1, silicon C1a is thick. A through-silicon via (TSV) T1 extending from each chip C1 is buried in silicon C1a.

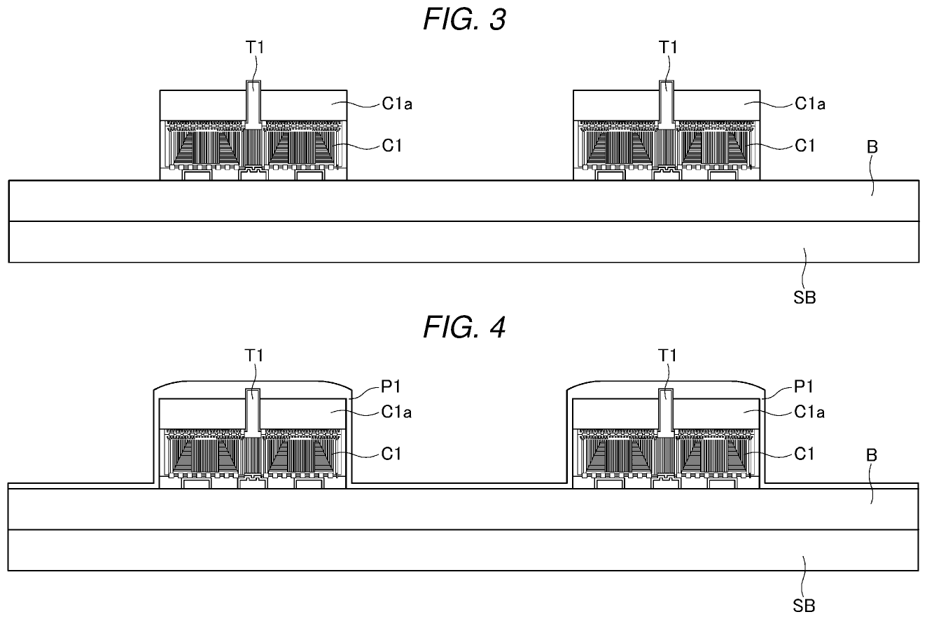

Next, as illustrated in FIG. 3, reactive ion etching (RIE) is performed on silicon C1a to expose a head of each through-silicon via T1.

Next, as illustrated in FIG. 4, a protective film P1 is formed to cover each chip C1, each silicon C1a, and the base substrate B. The protective film P1 in this example is a film comprising an oxide, a nitride, or a carbide formed by chemical vapor deposition (CVD) or the like. For example, a film such as a SiO₂ film, a SiOC film, a SiN film, or a SiCN film may be used as the protective film P1. In some examples, protective film P1 may be formed from an insulating film formed by coating process. The insulating film formed by coating may be formed from an organic film or a polymer material. In the coating, spin coating, inkjet printing, screen printing, or the like may be used. Whether formed by a coating process or chemical vapor deposition, the protective film P1 is formed to conform with an external shape of the chip C1. The protective film P1 may be adhesive as initially coated. The protective film P1 can then be cured when the protective film P1 and the chip C2 are heated after bonding.

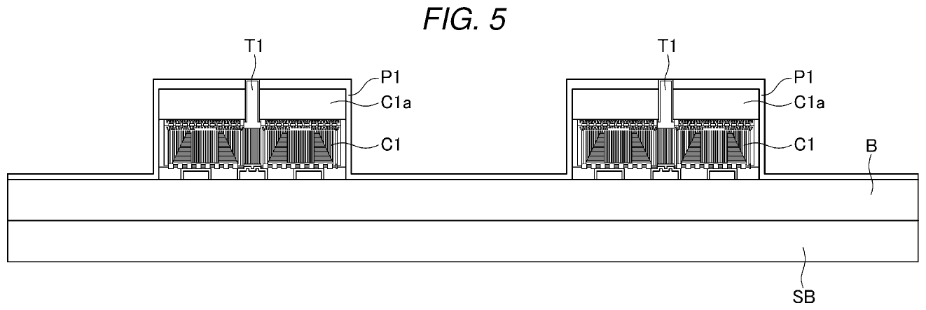

Next, as illustrated in FIG. 5, each protective film P1 is made thinner by chemical mechanical polishing (CMP). By performing the CMP, the through-silicon via T1 and the protective film P1 are formed to be flush (level) with each other. The through-silicon via T1 and the protective film P1 serve as a bonding surface. A pitch of the through-silicon via T1 may be, for example, 10 μm to 50 μm. A diameter of the through-silicon via T1 may be 5 μm to 30 μm. While through-silicon via T1 in this example is level with the upper surface of the protective film P1, in other examples the through-silicon via T1 may protrude somewhat from the protective film P1, for example, up to several microns (μm). Final polishing causes each chip C1 to have a thickness of approximately several tens of microns. The thickness is preferably approximately 20 μm to 70 μm. A thickness of each protective film P1 on the bonding surface after polishing may be approximately 3 μm to 5 μm.

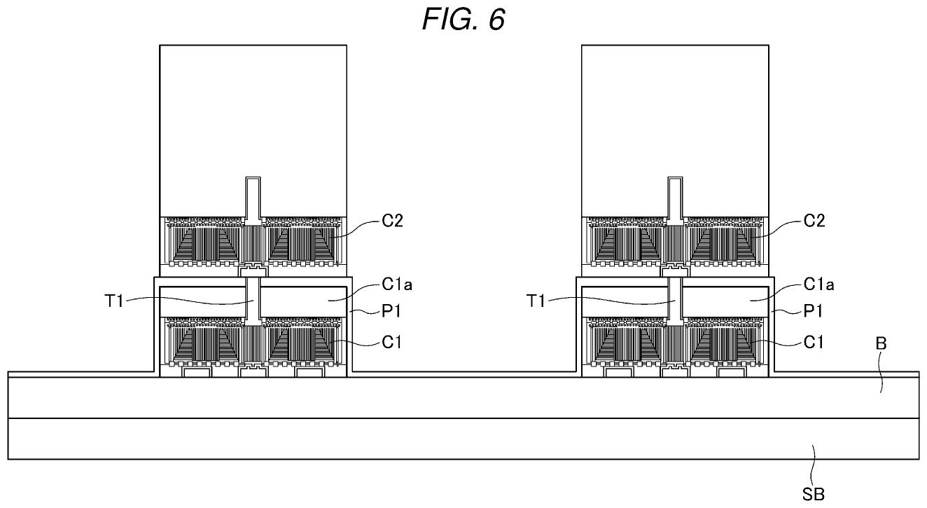

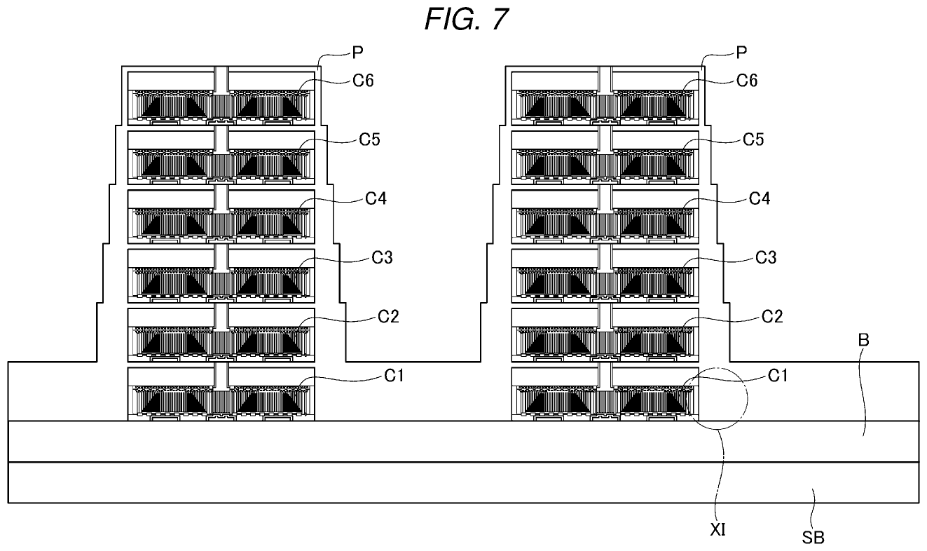

Next, as illustrated in FIG. 6, a next chip C2 is bonded onto the bonding surface of each chip C1. Subsequently, procedures described with reference to FIGS. 2 to 5 are repeated to stack the chips C3, C4, C5, and C6, thereby forming a chip stacked body. As illustrated in FIG. 7, a protective film P is formed whenever a chip C is stacked. Therefore, the protective film P on side surfaces of each lower chip will accumulate with additional chip stackings thereon. Thus, the protective film on the side surface of chips C1 will be thicker than the protective film P formed on the side surface of the chips C6.

An electrode is on a surface of the chip C2 facing the bonding surface of the chip C1, and an insulating film is formed around the electrodes. The electrodes and the insulating film may be formed flush with each other. In some examples, the electrode may protrude from the insulating film up to several microns. The insulating film formed on the surface of the chip C2 facing the bonding surface of the chip C1 may be either an organic film, a polymer material, or an inorganic film (such as an oxide film or a nitride film). The insulating film formed on the bonding surface of the chip C1 and the insulating film formed on the surface of the chip C2 facing the bonding surface of the chip C1 may be either the same material or different materials.

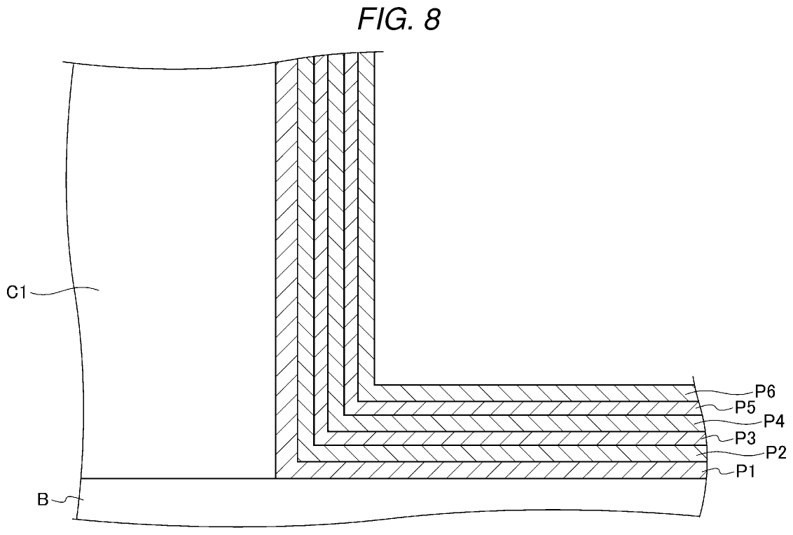

FIG. 8 is an enlarged view of part XI of FIG. 7. As illustrated in FIG. 8, the protective film P is comprised in in this portion by protective films P1, P2, P3, P4, P5, and P6 which are stacked in sequence during the chip stacking process. As described above, the protective film P1 is formed when the chip C1 is provided. The protective film P2 is then formed when the chip C2 is stacked on the chip C1. The protective film P3 formed when the chip C3 is stacked on the chip C2. The protective film P4 is formed when the chip C4 is stacked on the chip C3. The protective film P5 is formed when the chip C5 is stacked on the chip C4. The protective film P6 is formed when the chip C6 is stacked on the chip C5. After the chip C6 has been provided (stacked), a heat treatment may be performed to strengthen coupling of the contacting electrodes by metal diffusion. In some examples, a heat treatment may be performed after each chip stacking in turn, such as after the chip C2 is stacked on the chip C1, then another heat treatment may be performed after stacking the chip C3 on the chip C2, and so forth. However, in such a case, the chip C1 is subjected to a plurality of times of heat treatments and the upper chips are subjected to fewer. Therefore, it is typically more suitable to perform one heat treatment after the stacking of all the chips.

As illustrated in FIG. 8, six stacked films of the stacked protective films are provided on the side surfaces of the chip C1. Likewise, six stacked films of the stacked protective films are provided on the base substrate B.

The protective film P1 is not formed on the side surfaces of the chip C2 and stacking of protective films in this portion starts with the protective film P2, so that five stacked films (P2 to P6) form the protective film P on the chip C2. Likewise, the protective film P2 is not formed on the side surfaces of the chip C3 (nor is the protective film P1) and thus stacking starts with the protective film P3, so that just four stacked films (P3 to P6) form protective films P on the side surfaces of the chip C3.

Similarly, protective films P1, P2, and P3 are not formed on the side surfaces of the chip C4 and protective films P1, P2, P3, and P4 are not formed on the side surfaces of the chip C5. The side surface of the chip C6 has only the protective film P6 is thereon, so the protective film P is only one layer thick in this portion.

For the chip C6, there is no next chip to which the through-silicon via T1 is to be connected; thus, it is often unnecessary to make in the uppermost chip C6 any thinner. In such a case, stacked films might not need to be provided on the side surfaces of the chip C6. Therefore, the protective film P6 (illustrated in FIG. 8) might not be formed on the side surfaces of the chip C6 (or the other chips either) in some examples. Thus, just five protective films P (P1 to P5) would be provided on the side surfaces of the chip C1. Likewise, just the five protective films P (P1 to P5) would be provided on the base substrate B.

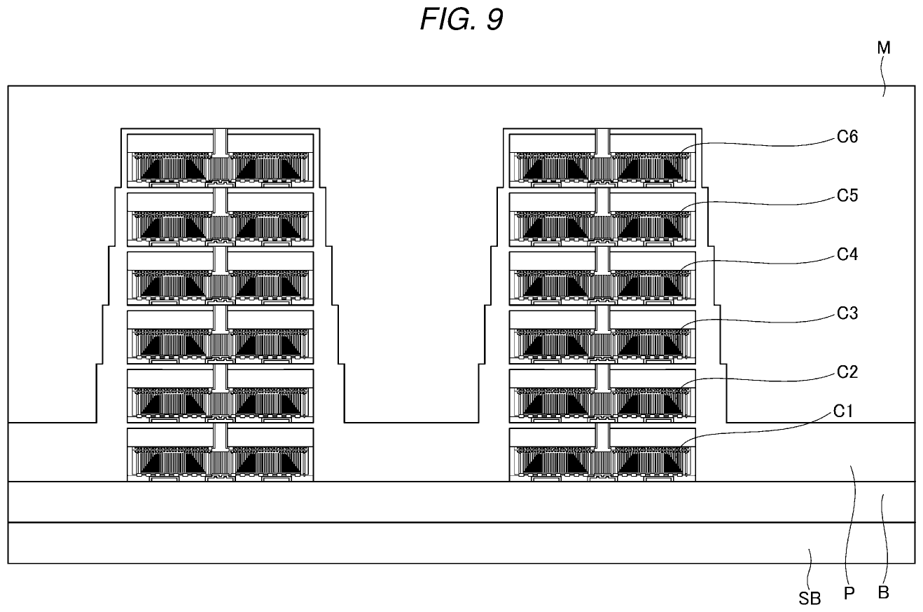

Next, as illustrated in FIG. 9, the mold resin layer M is formed. The supporting substrate SB can then be removed and dicing performed, thereby obtaining the individual semiconductor storage devices E as illustrated in FIG. 1. At this time, the protective films P are left partially exposed at side surfaces of the mold resin layer M. The exposed protective films P comprise stacked films and are obtained by repeatedly stacking SiN films (or the like) along a direction orthogonal to the surface of the base substrate B a plurality of times. The number of times of repetition may be equal to the number of stacked chips or smaller than the number of stacked chips by one. Before forming the mold resin layer M, the protective films P on the base substrate B may be removed in some examples. With such a removal, the protective films P would not be exposed at the side surfaces of the mold resin layer M.

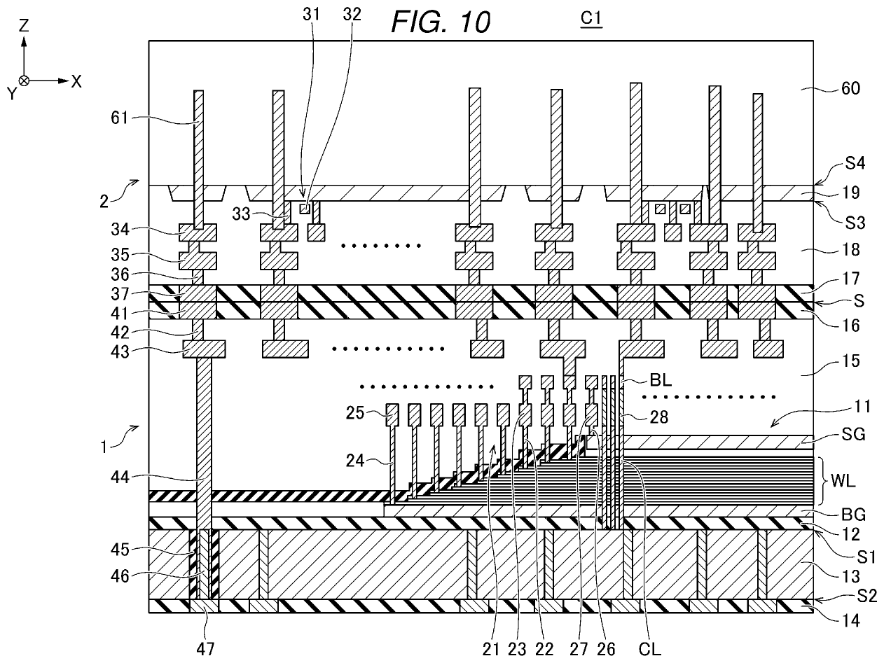

Next, the chip C1 will be further described with reference to FIG. 10. Description of the chip C1 can be taken as generally representative of chips C2 to C6 as well, but the chips C1 to C6 do not necessarily have to be identical to one another. FIG. 10 is a cross-sectional view of the chip C1 in the state described with reference to FIG. 2. As illustrated in FIG. 10, the chip C1 is a three-dimensional memory in which an array chip 1 and a circuit chip 2 have been bonded to each other.

The array chip 1 includes a memory cell array 11, an insulating film 12, a substrate 13, and an insulating film 14. The memory cell array 11 includes a plurality of memory cells. The insulating film 12 is provided under the memory cell array 11. The substrate 13 is provided under the insulating film 12. The insulating film 14 is provided under the substrate 13.

The array chip 1 further includes an interlayer insulating film 15 and an insulating film 16. The interlayer insulating film 15 is provided on the memory cell array 11. The insulating film 16 is provided on the interlayer insulating film 15. The insulating films 12, 14, and 16 are, for example, silicon oxide films or silicon nitride films. The substrate 13 is, for example, a semiconductor substrate such as a silicon substrate.

The circuit chip 2 is provided on the array chip 1. A reference symbol S indicates a bonding surface between the array chip 1 and the circuit chip 2. After being formed, the array chip 1 and the circuit chip 2 are applied to each other (bonded). The circuit chip 2 includes an insulating film 17, an interlayer insulating film 18 and a semiconductor layer 19. The interlayer insulating film 18 is provided on the insulating film 17. The semiconductor layer 19 is provided on the interlayer insulating film 18. The insulating film 17 is, for example, a silicon oxide film or a silicon nitride film.

The Z direction depicted in FIG. 10 may or may not coincide with the gravitational direction.

The array chip 1 includes a plurality of word lines WL, a back gate BG, and a select gate line SG as electrode layers in the memory cell array 11. FIG. 10 illustrates a staircase structure portion 21 of the memory cell array 11. The array chip 1 and the circuit chip 2 are joined together.

As illustrated in FIG. 10, each word line WL is electrically connected to a word interconnection layer 23 via a contact plug 22. The back gate BG is electrically connected to a back gate interconnection layer 25 via a contact plug 24. The select gate SG is electrically connected to a select gate interconnection layer 27 via a contact plug 26. A columnar portion CL penetrates the select gate SG. The word lines WL, the back gate BG, and the columnar portion CL are electrically connected to a bit line BL via a via plug 28 and electrically connected to the substrate 13.

The circuit chip 2 includes a plurality of transistors 31. Each transistor 31 includes a gate electrode 32, a source diffusion region, and a drain diffusion region. The gate electrode 32 is provided on the semiconductor layer 19 via a gate insulating film. The source diffusion region and the drain diffusion region are provided in the semiconductor layer 19.

The circuit chip 2 further includes a plug 33, an interconnection layer 34, and an interconnection layer 35. A plurality of plugs 33 are provided on the source diffusion regions or the drain diffusion regions of the transistors 31. A plurality of interconnection layers 34 are provided on these plugs 33, and each interconnection layer 34 includes a plurality of interconnections therein. A plurality of interconnection layers 35 are provided on these interconnection layers 34, and each interconnection layer 35 includes a plurality of interconnections therein.

The circuit chip 2 further includes a via plug 36 and a metal pad 37. A plurality of via plugs 36 are provided on the interconnection layers 35. A plurality of metal pads 37 are provided on these via plugs 36 in the insulating film 17.

The circuit chip 2 further includes the substrate 60 and a through-silicon via 61. The substrate 60 is provided on the surface S4 of the semiconductor layer 19. The substrate 60 is, for example, a silicon oxide material or a silicon material. The through-silicon via 61 is provided in the interlayer insulating film 18, the semiconductor layer 19, and the substrate 60, and provided on the interconnection layers 34. The substrate 60 corresponds to the silicon C1a depicted in FIGS. 2 and the like. The through-silicon via 61 corresponds to the through-silicon via T1 depicted in FIGS. 2 and the like. For example, the through-silicon via 61 is buried (formed) in the substrate 60 before the forming of the interconnection layers 34. The circuit chip 2 includes a CMOS control circuit (logical circuit) that controls the array chip 1.

The array chip 1 includes a metal pad 41, a via plug 42, and an interconnection layer 43. A plurality of metal pads 41 are provided on the metal pads 37 in the insulating film 16. A plurality of via plugs 42 are provided on the metal pads 41. A plurality of interconnection layers 43 are provided on these via plugs 42 and each interconnection layer 43 includes a plurality of interconnections. Each of the word lines WL and the bit lines BL is electrically connected to a corresponding interconnection in an interconnection layer 43.

The array chip 1 further includes a plug 44, a plug 46, and a metal pad 47. The plug 44 is provided in the interlayer insulating film 15 and the insulating film 12 and provided on the interconnection layer 43. The plug 46 is provided in the substrate 13 and the insulating film 14 via an insulating film 45 and provided on the plug 44. The metal pad 47 is provided in the interlayer insulating film 14 and provided on the plug 46. The metal pad 47 is provided flush with a lower surface of the insulating film 14. The metal pad 47 is an external connection pad for the chip C1.

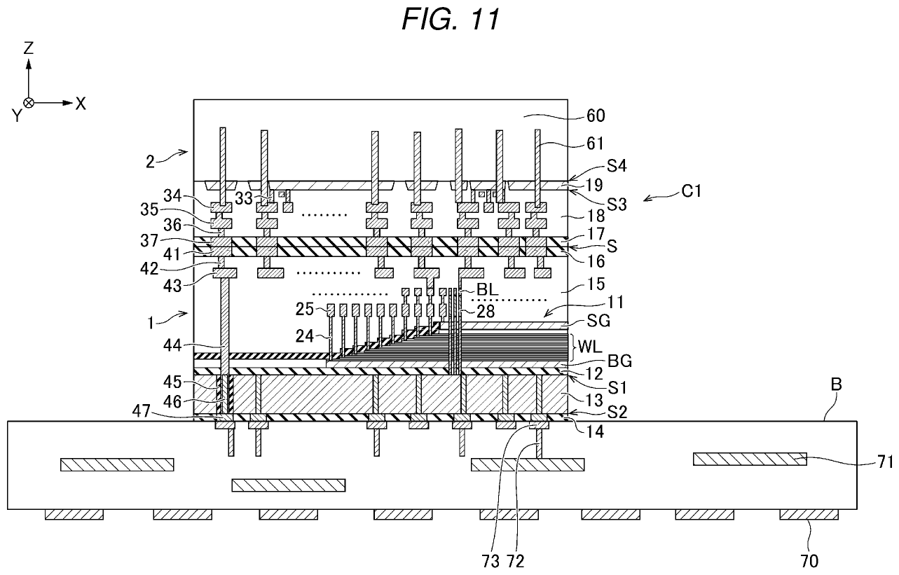

FIG. 11 is a cross-sectional view of the chip C1 joined to the base substrate B by bonding. The base substrate B includes an external terminal 70, an interconnection layer 71, a plug 72, and a metal pad 73. A plurality of external terminals 70 are provided under the base substrate B. The external terminals 70 are metal terminals for external connection and function similarly to the metal balls BE described with reference to FIG. 1.

The interconnection layer 71 is provided in the base substrate B and includes a plurality of interconnections. The plug 72 is provided in the base substrate B and provided on the interconnection layer 71. The metal pad 73 is provided on the plug 72. The metal pad 73 is provided in the base substrate B and provided flush with an upper surface of the base substrate B.

The metal pad 47 of the chip C1 and the metal pad 73 of the base substrate B disposed at corresponding positions are joined together by bonding.

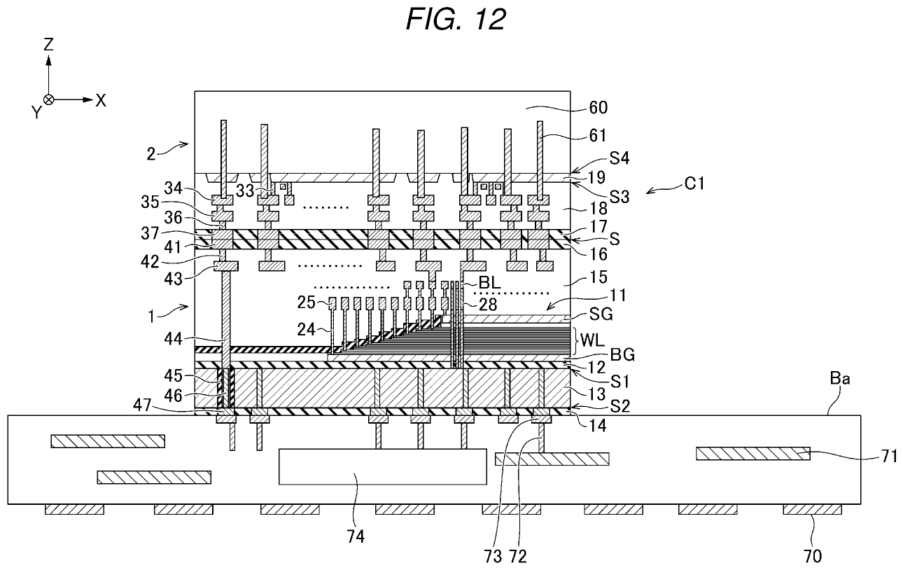

A controller may be provided in the base substrate B. FIG. 12 illustrates an example of a base substrate Ba in which a controller 74 is provided. The controller 74 controls the chip C1 and the like. The controller 74 is connected to a metal pad 73 by a plug 72.

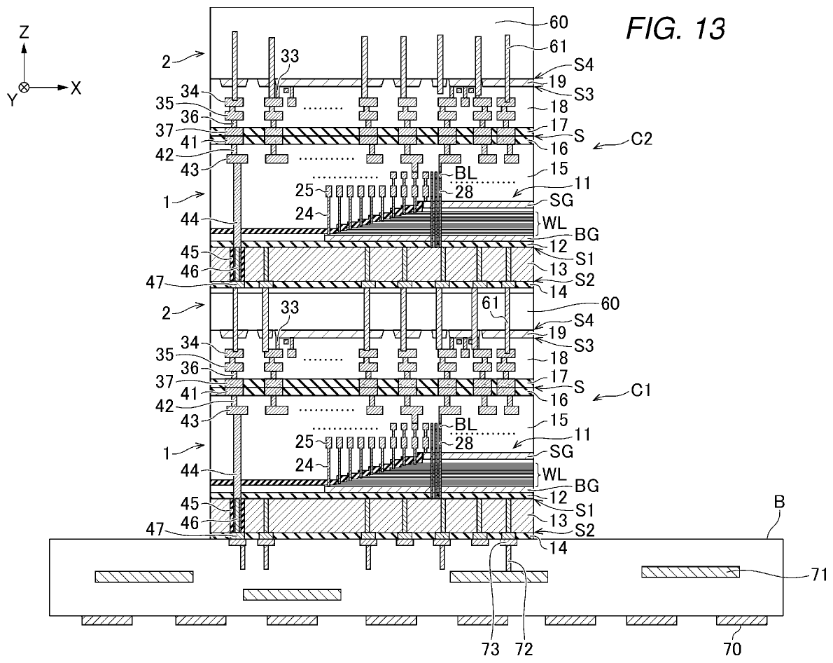

FIG. 13 is a cross-sectional view of the chip C2 bonded to the chip C1 illustrated in FIG. 11. After the state illustrated in FIG. 11, a head of each through-silicon via 61 of the chip C1 was exposed by the method described with reference to FIGS. 3 to 6 and the chip C2 was placed on the chip C1. The through-silicon via 61 of the chip C1 and the metal pad 47 of the chip C2 disposed at corresponding positions joined together by bonding. A surface of the chip C2 facing the chip C1 is formed from, for example, an insulating film such as a silicon oxide film and may be formed flush with the pads 47. A surface of the chip C1 facing the chip C2 is formed from, for example, an insulating film such as a silicon oxide film and may be formed flush with the ends of the through-silicon vias 61.

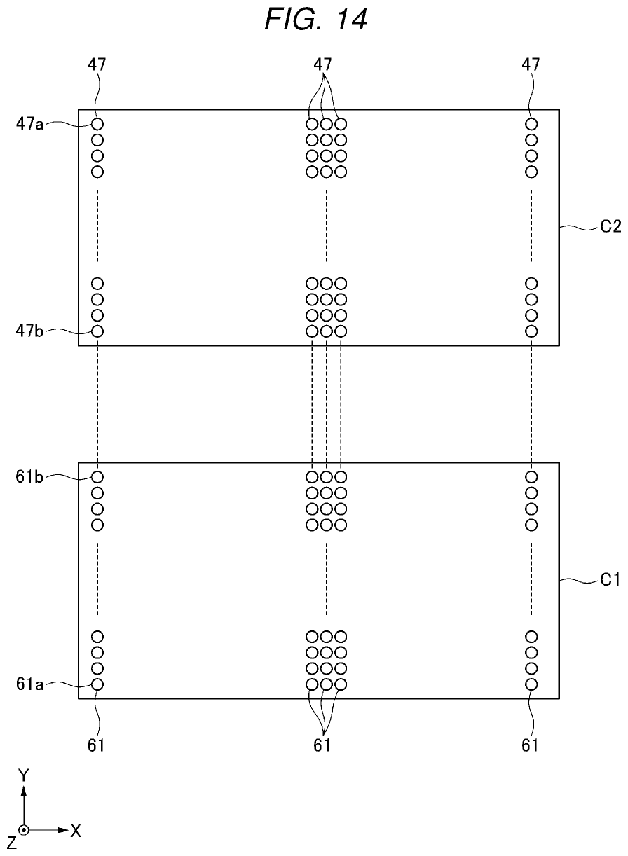

A case where the through-silicon vias 61 of the chip C1 and the metal pads 47 of the chip C2 are disposed as illustrated in FIG. 14 will be described as an explanatory example. FIG. 14 illustrates an upper surface of the chip C1 and a lower surface of the chip C2. In the example illustrated in FIG. 14, a through-silicon via 61a corresponds to a metal pad 47a, and a through-silicon via 61b corresponds to a metal pad 47b. The chip C2 is placed on and bonded onto the chip C1 so that these corresponding elements are opposed to each other.

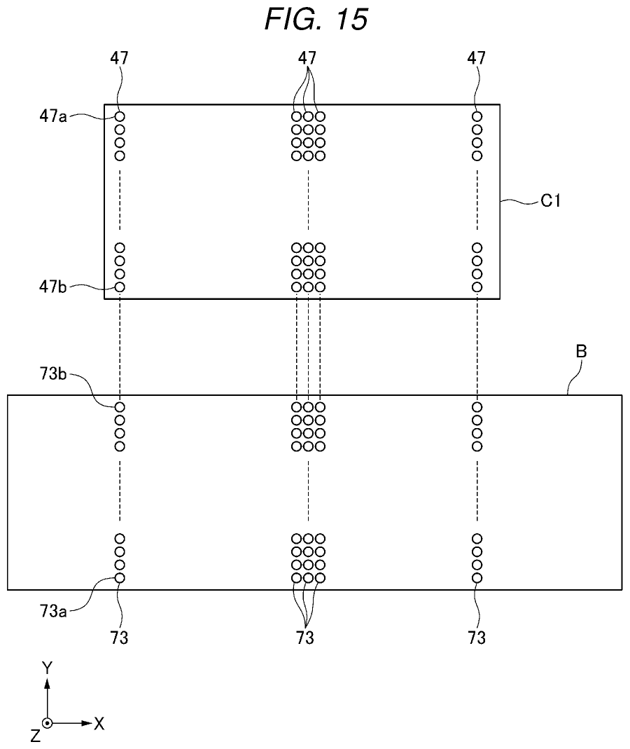

A case where the chip C1 is joined to the base substrate B will be described with reference to FIG. 15. FIG. 15 illustrates the upper surface of the base substrate B and a lower surface of the chip C1. In the example illustrated in FIG. 15, a metal pad 73a corresponds to the metal pad 47a, and a metal pad 73b corresponds to a metal pad 47b. The chip C1 is placed on and bonded onto the base substrate B so that these corresponding elements are opposed to each other.

The example in which the metal pads 73 are disposed linearly along a short side of the base substrate B and the metal pads 47 are similarly disposed linearly along a short side of the chip C1 is described with reference to FIG. 15. However, the arrangement of the metal pads 73 and 47 is not limited to this example.

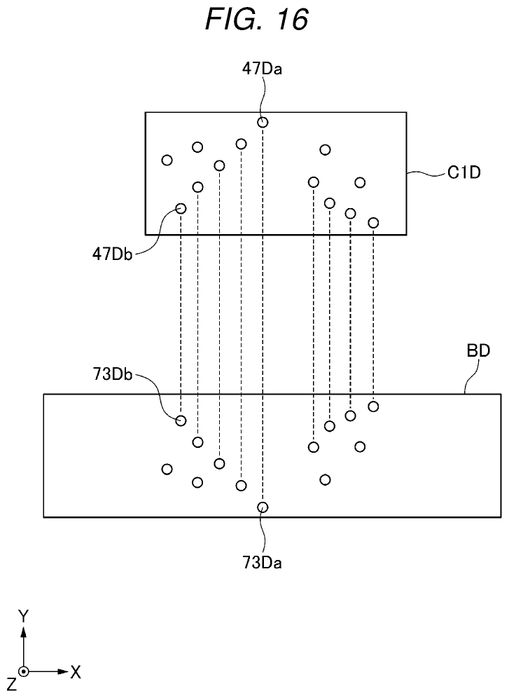

As illustrated in FIG. 16, the metal pads 73 and 47 may be disposed irregularly. FIG. 16 illustrates an upper surface of a base substrate BD and a lower surface of a chip C1D. In the example illustrated in FIG. 16, a metal pad 73Da corresponds to a metal pad 47Da, and a metal pad 73Db corresponds to a metal pad 47Db. The chip C1D is placed on and bonded to the base substrate BD so that these corresponding elements are opposed to each other. As illustrated in FIG. 16, the arrangement of the metal pads of the chip C1 may be changed in accordance with the arrangement of the metal pads of the base substrate BD or wiring may be arranged again without changing the arrangement of the metal pads of the chip C1 illustrated in FIG. 15.

FIG. 17 illustrates a semiconductor storage device E1 using the base substrate Ba (described with reference to FIG. 12). As illustrated in FIG. 17, the controller 74 is provided in the base substrate Ba. The interconnection layer 71 is provided in the base substrate Ba. The chips C are stacked on the base substrate Ba. The type of the chips C is not limited to chips obtained by joining a memory substrate to a CMOS (complementary Metal-oxide Semiconductor) like the chip C1 (described with reference to FIGS. 10 and the like). The chips C may be, for example, configured only with a memory substrate. The protective films P are provided on outer peripheries of a plurality of stacked chips C. The mold resin layer M covers the protective films P.

FIG. 18 illustrates configurations of a semiconductor storage device E2 according to a second embodiment. The semiconductor storage device E2 includes the base substrate B and the plurality of chips C. The chips C are held on the base substrate B while being supported by adhesive portions 81. The base substrate B is electrically connected to the chips C by a connection electrode 82. On the base substrate B, a plurality of metal balls BE are joined to an opposite surface to a surface onto which the chips C are joined.

A through-silicon via T is provided in each of the plurality of chips C. Protective films P cover side surfaces of the plurality of chips C. The protective film P may be partially or fully removed in some examples. A mold resin layer M covers the protective film P in this example.

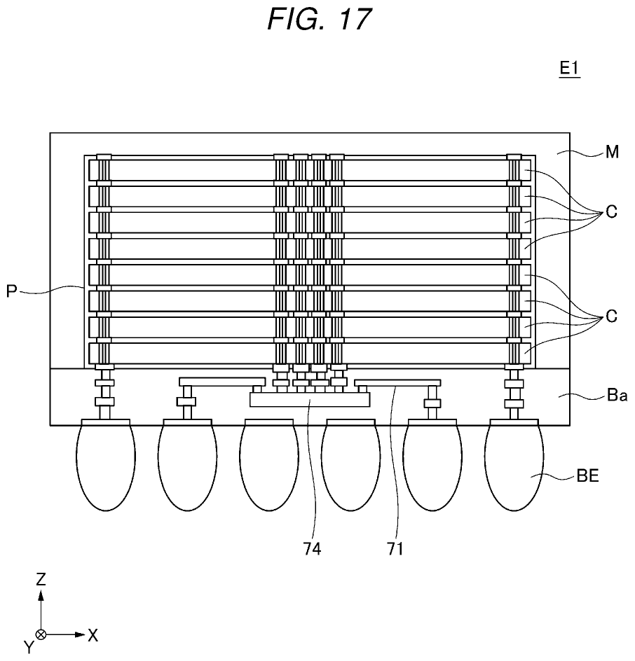

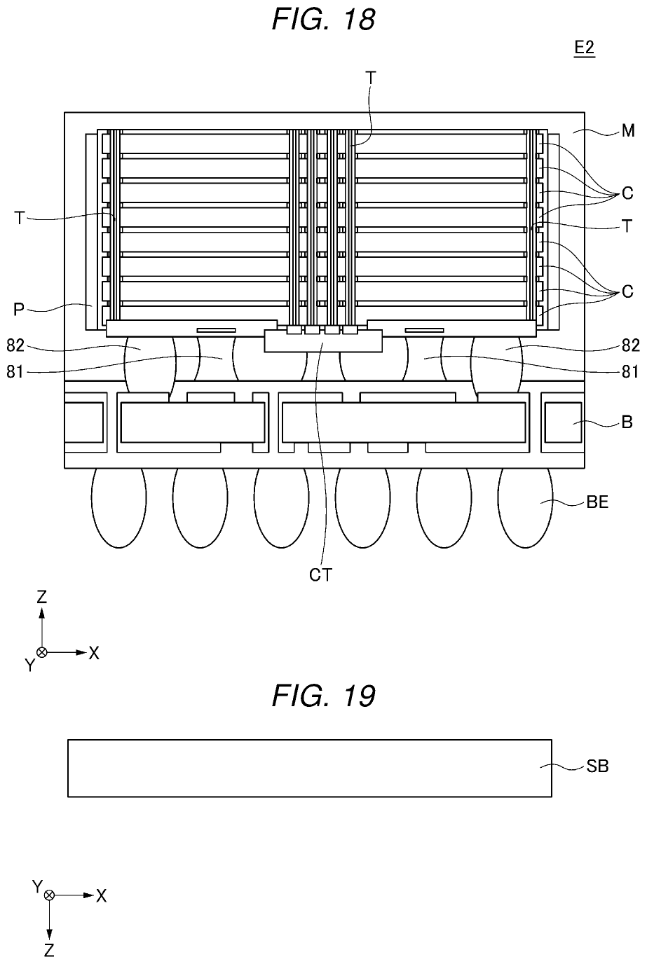

Next, a method of manufacturing the semiconductor storage device E2 will be described with reference to FIGS. 19 to 28. FIGS. 19 to 28 illustrate an example of mounting two chips C, though may be similarly stacked.

As illustrated in FIG. 19, the supporting substrate SB is prepared. The supporting substrate SB is a substrate to be removed before the end of manufacturing.

Next, as illustrated in FIG. 20, the chip C is joined onto the supporting substrate SB by an adhesive or the like. The through-silicon vias T are provided in the chip C as schematically depicted.

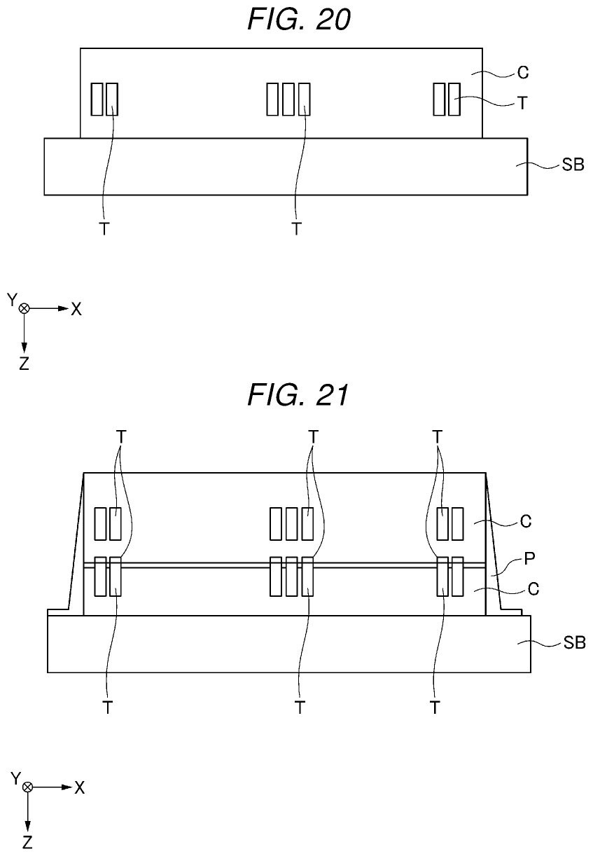

Next, as illustrated in FIG. 21, the protective film P for the chip C on the supporting substrate SB is formed, the head of each of the through-silicon vias T is then exposed, and the next chip C is joined. The through-silicon vias T of the joined chips C are joined to each other. The chips C are joined together by bonding.

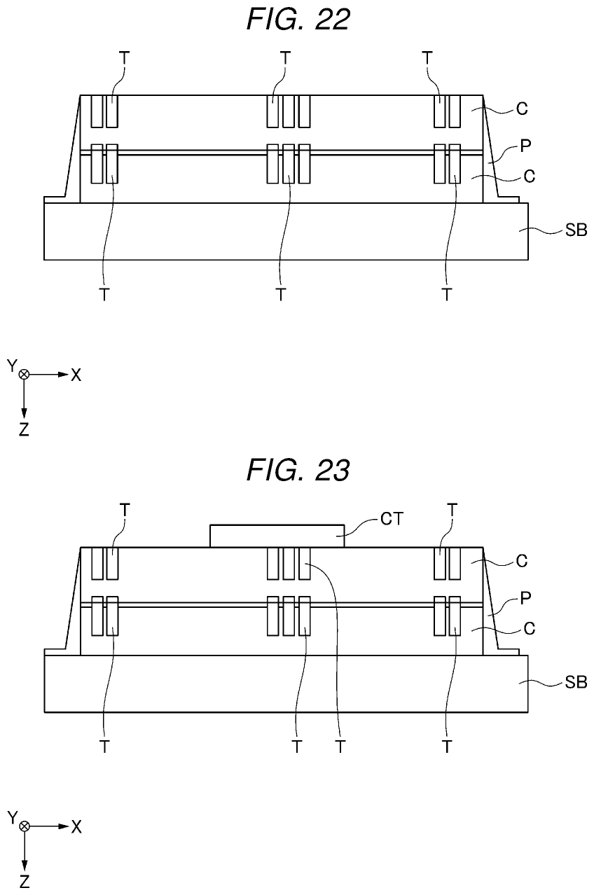

Next, as illustrated in FIG. 22, the protective film P is provided for the upper chip C, and the through-silicon vias T are exposed by exposing the heads of the through-silicon vias T by polishing or the like.

Next, as illustrated in FIG. 23, a control chip CT is connected to the upper chip C. The control chip CT is joined to the through-silicon vias T of the upper chip C.

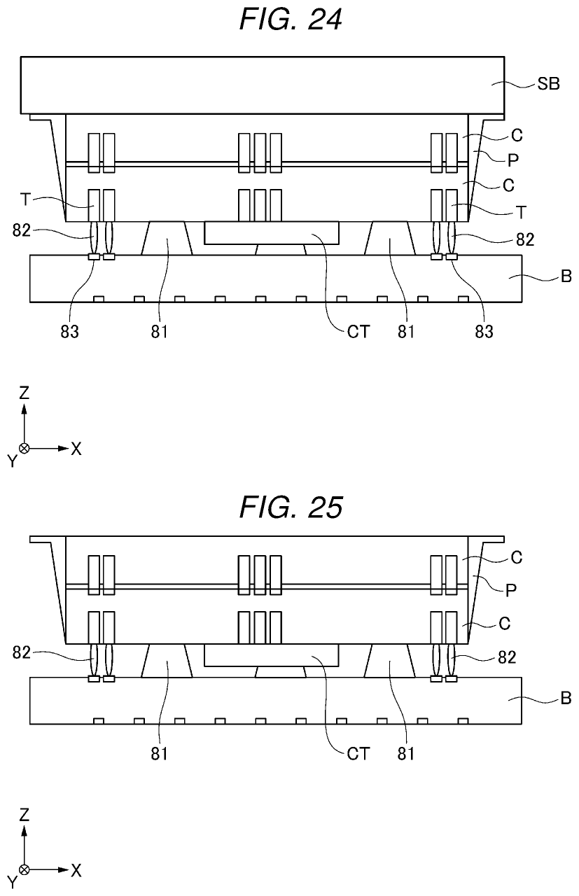

Next, as illustrated in FIG. 24, the base substrate B is prepared. The base substrate B includes an interconnection layer therein. The base substrate B includes metal pads 83 provided in an upper portion. The supporting substrate SB and the chips C illustrated in FIG. 23 are turned upside down and adhesively bonded to the base substrate B. The supporting substrate SB and the chips C are adhesively bonded to the base substrate B by adhesive portions 81. The adhesive portions 81 also serve as supports that hold the chips C on the base substrate B at predetermined intervals. The chips C are electrically connected to the base substrate B by electrodes 82. The electrodes 82 are each coupled to one through-silicon via T and one metal pad 83.

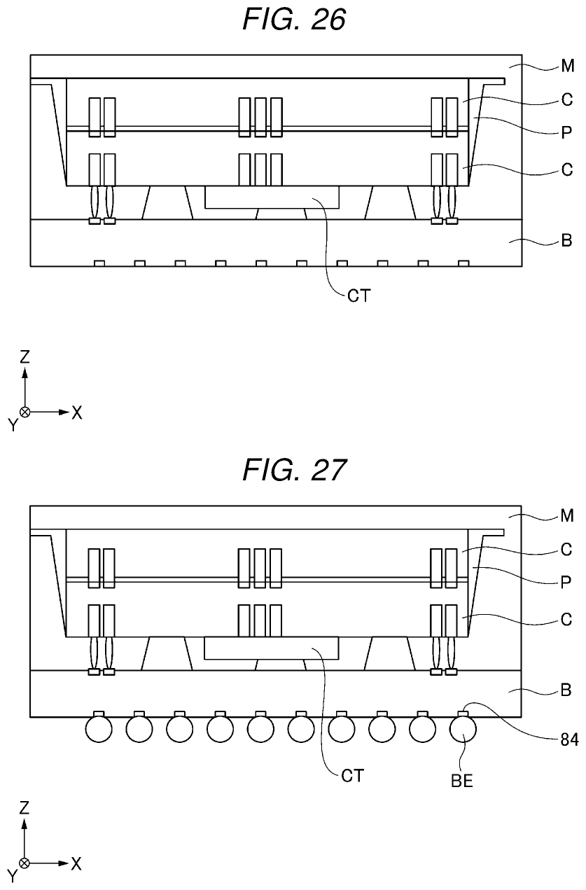

Next, as illustrated in FIG. 25, the supporting substrate SB is removed. Next, as illustrated in FIG. 26, a mold resin is filled to cover the chips C on the base substrate B to form the mold resin layer M.

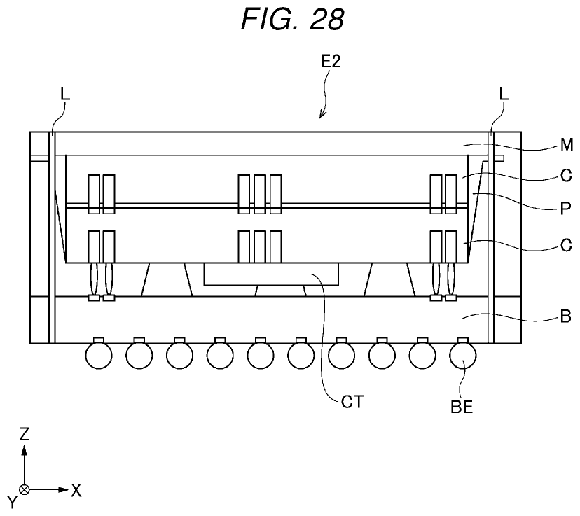

Next, as illustrated in FIG. 27, the metal balls BE are joined to a lower portion of the base substrate B. The metal balls BE are joined to the metal pad 83 provided on the lower surface of the base substrate B. Next, as illustrated in FIG. 28, the structure is cut along cut lines L for dicing, thereby obtaining the semiconductor storage device E2. At this time, the protective film P may be partially exposed at the side surfaces of the mold resin layer M. Unlike the semiconductor device E illustrated in FIG. 1, the protective film P is exposed at positions near the chips C farthest from the base substrate B. Before forming the mold resin layer M, the protective film P on the base substrate B may be removed. In this case, the protective film P would not be exposed at the side surfaces of the mold resin layer M.

Each of the semiconductor devices E, E1, and E2 includes a base substrate including an interconnection layer. A plurality of chips are stacked on the base substrate. Electrodes and protective films are provided between the plurality of chips. The protective films are also provided on the side surfaces of the chip.

A protective film P in an example includes at least one of SiO₂, SiOC, SiN, and SiCN. The protective film P can be an insulating film formed by a coating process in some examples.

A thickness of the protective film P provided on the side surfaces of the chips C on the side closer to the base substrate B differs from a thickness on the side closer to an upper end of the chips C. A plurality of protective films P can be stacked on the side surfaces of the chips C.

A method of manufacturing each of the semiconductor devices E, E1, and E2 includes: preparing a base substrate including an interconnection layer; joining a chip including electrodes onto the base substrate; forming a protective film for the chip; processing the protective film P for the chip to make the protective film thinner made thinner to expose a head of the electrodes for bonding to another chip or the like.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a base substrate including an interconnection layer;
a plurality of chips stacked on the base substrate; and
a protective film between each adjacent pair of chips in the plurality of chips stacked on the base substrate and on side surfaces of at least each chip in the plurality other than an uppermost chip in the stacked plurality of chips, wherein
a lowermost chip in the stacked plurality of chips has a metal pad electrically connected to the interconnection layer, and
each chip in an adjacent pair of chips in the plurality of chips stacked on the base substrate has an electrode contacting an electrode of the other chip in the adjacent pair.

2. The semiconductor device according to claim 1, wherein the protective film comprises at least one of SiO₂, SiOC, SiN, and SiCN.

3. The semiconductor device according to claim 1, wherein the protective film is an insulating film formed by a coating process.

4. The semiconductor device according to claim 3, wherein the coating process is a spin coating process.

5. The semiconductor device according to claim 1, wherein the base substrate includes a controller in an interior of the base substrate.

6. The semiconductor device according to claim 1, wherein each chip of the plurality of chips comprises a memory array chip bonded to a peripheral circuit chip.

7. The semiconductor device according to claim 6, wherein the electrode of each chip is a through-silicon via.

8. The semiconductor device according to claim 1, wherein the electrode of each chip is a through-silicon via.

9. The semiconductor device according to claim 1, wherein a thickness of the protective film on the side surfaces of the lowermost chip is thicker than a thickness of the protective film on the side surfaces of the uppermost chip.

10. The semiconductor device according to claim 1, wherein the protective film is on side surfaces of the uppermost chip.

11. The semiconductor device according to claim 10, wherein
the protective film is a single layer on the side surfaces of the uppermost chip, and
the protective film is a plurality of layers on the side surfaces of the lowermost chip.

12. The semiconductor device according to claim 11, wherein the number of layers in the plurality of layers on the side surfaces of the lowermost chip is equal to the number of chips in the plurality of chips stacked on the substrate.

13. The semiconductor device according to claim 1, wherein the protective film is on an upper surface of the base substrate on which the plurality of chips are stacked.

14. The semiconductor device according to claim 13, further comprising:
a molded resin layer covering the protective layer, the plurality of chips, and the upper surface of the base substrate, wherein
the protective film is exposed an outer edge surface of the molded resin layer.

15. The semiconductor device according to claim 1, further comprising:
a molded resin layer covering the protective layer, the plurality of chips, and an upper surface of the base substrate.

16. The semiconductor device according to claim 15, wherein the protective film is exposed an outer edge surface of the molded resin layer.

17. A semiconductor device, comprising:
a base substrate including an interconnection layer;
a plurality of memory chips stacked on the base substrate; and
a protective film between each adjacent pair of memory chips in the plurality of memory chips stacked on the base substrate and on side surfaces of at least each chip in the plurality other than an uppermost memory chip in the stacked plurality of memory chips, wherein
each chip in an adjacent pair of memory chips in the plurality of memory chips stacked on the base substrate has through-silicon via contacting through-silicon via of the other chip in the adjacent pair, and
a through-silicon via of the lowermost memory chip in the stacked plurality of memory chips is electrically connected to the interconnection layer.

18. The semiconductor device according to claim 17, wherein a thickness of the protective film on the side surfaces of the lowermost memory chip is thicker than a thickness of the protective film on the side surfaces of the uppermost memory chip.

19. The semiconductor device according to claim 17, wherein
the protective film is on side surfaces of the uppermost memory chip,
the protective film is a single layer on the side surfaces of the uppermost memory chip, and
the protective film is a plurality of layers on the side surfaces of the lowermost memory chip.

20. A method of manufacturing a semiconductor device, the method comprising:
preparing a base substrate including an interconnection layer;
bonding a first chip to a surface of the base substrate, the first chip having an electrode extending therethrough in a direction orthogonal to the surface of the base substrate;
forming a first protective film to cover the first chip;
thinning an upper portion of the first protective film on the first chip and exposing a head portion of the electrode to the first chip;
bonding a second chip to the first chip bonded to the base substrate, the second chip having an electrode extending therethrough; and
forming a second protective film to cover the second chip, wherein
the first protective film includes a portion on a side surface of the first chip, and
the second protective film includes a portion on a side surface of the second chip and a portion on the side surface of the first chip.
